(19) United States
(12) Patent Application Publication
(10) Pub. No.: US 2010/0209843 A1
(43) Pub. Date: Aug. 19, 2010

(54) PROCESS FOR THICK FILM CIRCUIT PATTERNING

(75) Inventor: ATSUHIKO SATO, UTSUNOMIYA-SHI (JP)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E. I. DU PONT DE NEMOURS AND COMPANY, Wilmington, DE (US)

(21) Appl. No.: 12/371,676

(22) Filed: Feb. 16, 2009

(51) Int. Cl. G03F 7/20

(52) U.S. Cl. 430/198; 430/315

(57) ABSTRACT

The invention relates to forming an electrically functional pattern on a substrate. More specifically, the invention relates to a process for using a photosensitive element in combination with a sheet having a thick film composition applied to a support.

### FIELD OF THE INVENTION

The invention relates to forming an electrically functional pattern on a substrate. More specifically, the invention relates to a process for using a photosensitive element in combination with a sheet having a thick film composition applied to a support.

### BACKGROUND OF INVENTION

U.S. Pat. No. 7,052,824, included erein by response, discloses a method for forming a thick film circuit as follows. A photohardenable tacky layer is applied onto a substrate, the photohardenable tacky layer is exposed to a desired pattern and a reverse pattern, and a thick film composition is caused to adhere to non-exposed positions that retain a tacky surface, to form thereby a patterned article in which no thick film composition is adhered at exposed and hardened positions. When this patterned article is heated, the photohardenable tacky layer, including the cured portions, is scattered away, and the thick film becomes directly sintered on the substrate.

Excitation is inhibited by the quenching effect of oxygen when the photocuring initiator comprised in the photohardenable tacky layer comes into contact with air. The quenching effect denotes herein an effect whereby the excitation energy of a molecule disappears, or is converted to thermal energy, in a reaction between a molecule and light, through the influence of, for instance, heat, infrared rays or oxygen. Therefore, when exposing the photohardenable tacky layer to the natural atmosphere, where oxygen is present, the inner side of the tacky layer, which is not in contact with oxygen, becomes cured, but the surface of the tacky layer, which is in contact with air, remains often uncured. When the surface of the tacky layer is not cured to a desired pattern, a thick film layer fails to be transferred in the desired pattern during adhesion of the thick film layer of a transfer sheet in a subsequent step.

In an example of U.S. Pat. No. 7,052,824, the photohardenable tacky layer has a cover sheet comprising polyethylene terephthalate or the like on the surface. The photohardenable tacky layer is exposed from above the cover sheet, and hence the photohardenable tacky layer does not come into contact with oxygen, whereby the above problem does not occur. When the transfer region is large, however, it is not easy to strip the cover sheet without missing portions in the photohardenable tacky layer. Hence, it would be desirable to do away with the cover sheet.

### SUMMARY OF THE INVENTION

An objective of this present invention is to provide a method for forming a thick film pattern, wherein defects do not readily occur in a transferred thick film pattern, even when exposure is carried out without a cover sheet on a photohardenable tacky layer. The present invention is directed to a process for forming a pattern having electrically functional properties on a substrate comprising the steps of: (a) providing a photosensitive layer having a tacky surface disposed on a substrate, (b) image-wise exposing the photosensitive tacky surface to form an imaged layer having tacky and non-tacky areas; (c) heating the photosensitive layer; (d) applying a sheet comprising at least one layer of a thick film composition disposed on a support to the imaged layer wherein the imaged layer is in contact with the thick film composition of the sheet; (e) removing the support wherein the thick film composition remains on the support in the non-tacky areas of the imaged layer and the thick film composition substantially adheres to the tacky areas of the imaged layer forming a patterned article; and (f) firing or curing the thick film composition of the patterned article. The heating temperature in the step (c) is preferably from 50° C. to 100° C. The heating time in the step (c) is preferably from 3 minutes to 40 minutes. The exposure amount in the step (b) is from 100 mJ/cm² to 1000 mJ/cm². The above process also may be practiced without exposure of a tacky surface resulting in full coverage of the tacky surface by the thick film composition.

### BRIEF DESCRIPTION OF THE DRAWINGS

FIG. 1 is an illustrative diagram depicting an embodiment of the process of the present invention.

### DETAILED DESCRIPTION OF THE INVENTION

In the present invention, uncured portions on a tacky layer, on account of the quenching effect, are scattered through heating of the photohardenable tacky layer after exposure. In a subsequent step, the thick film composition of a transfer sheet can thus be appropriately adhered, in a desired pattern, to the photohardenable tacky layer. Generally, a thick film composition comprises a functional phase that imparts appropriate electrically functional properties, such as, conductive, resistive and dielectric properties. The functional phase comprises electrically functional powders dispersed in an organic medium that acts as a carrier for the functional phase. The functional phase determines the electrical properties and influences mechanical properties of a dried thick film. There are two main types of thick film compositions that may be utilized in this invention. Both are conventional products sold in the electronics industry. First, thick film compositions wherein the organics of the compositions during processing is burned or fired out are referred to as “firable thick film compositions”. They typically comprise conductive, resistive or dielectric powders and inorganic binder dispersed in organic medium. Prior to firing, a processing requirement may include an optional heat treatment such as: drying, curing, reflow, soldering and others known to those skilled in the art of thick film technology.

Second, thick film compositions that typically comprise conductive, resistive or dielectric powders and are dispersed in organic medium wherein the compositions during processing are cured and the organics remains are referred to as “polymer thick film compositions”. Fireable thick film compositions and polymer thick film compositions are generally referred to as “thick film compositions”. “Organics” comprise polymer or resin components of a thick film composition.

In conductor applications the functional phase is comprised of electrically functional conductor powder(s). The electrically functional powders in a given thick film composition may comprise a single type of powder, mixtures of powders, alloys or compounds of several elements. Examples of such powders include: gold, silver, copper, nickel, aluminum, platinum, palladium, molybdenum, tungsten, tantalum, tin, indium, lanthanum, gadolinium, boron, ruthenium, cobalt, titanium, yttrium, europium, gallium, sulfur, zinc, silicon, magnesium, barium, cerium, strontium, lead, antimony, conductive carbon, and combinations thereof and others common in the art of thick film compositions.

In resistor compositions, the functional phase is generally a conductive oxide. Examples of the functional phase in resistor compositions are Pd/Ag and RuO₂. Other examples include ruthenium pyrochlore oxide which is a multi-component compound of RU⁺⁴, IR⁺⁴ or a mixture of these (M″), said compound being expressed by the following general formula: (MₓBi₂₋ₓ) (MYM_{2-y})0_{7-z} wherein M is selected from the group consisting of yttrium, thallium, indium, cadmium, lead, copper and rare earth metals, M′ is selected from the group consisting of platinum, titanium, chromium, rhodium and antimony, M″ is ruthenium, iridium or a mixture thereof, x denotes 0 to 2 with a proviso that x.ltoreq.1 for monovalent copper, y denotes 0 to 0.5 with the proviso that when M′ is rhodium or two or more of platinum, titanium, chromium, rhodium and antimony, y stands for 0 to 1, and z denotes 0 to 1 with a proviso that when M is divalent lead or cadmium, z is at least equal to about x/2.

These ruthenium pyrochlore oxides are described in detail in the specification of U.S. Pat. No. 3,583,931. The preferred ruthenium pyrochlore oxides are bismuth ruthenate (Bi₂Ru₂O₇) and lead ruthenate (Pb₂Ru₂O₆).

In dielectric compositions, the functional phase is generally a glass or ceramic. Dielectric thick film compositions are nonconductive compositions or insulator compositions that separate electrical charges and may result in the storage of an electrical charge. Therefore, the thick film dielectric compositions typically contain ceramic powders, oxide and non-oxide frits, crystallization initiator or inhibitor, surfactants, colorants, organic mediums, and other components common in the art of such thick film dielectric compositions. Examples of ceramic solids include: alumina, titanates, zirconates and stannates, BaTiO₃, CaTiO₃, SrTiO₃, PbTiO₃, CaZrO₃, BaZrO₃, CaSnO₃, BaSnO₃ and Al₂O₃, glass and glass-ceramic. It is also applicable to precursors of such materials, i.e., solid materials which upon firing are converted to dielectric solids, and to mixtures thereof.

The powders described hereinabove are finely dispersed in an organic medium and are optionally accompanied by, inorganic binders, metal oxides, ceramics, and fillers, such as other powders or solids. The function of an inorganic binder in a thick film composition is binding the particles to one another and to the substrate after firing. Examples of inorganic binders include glass binders (frits), metal oxides and ceramics. Glass binders useful in the thick film composition are conventional in the art. Some examples include borosilicates and aluminosilicates glasses. Examples further include combinations of oxides, such as: B₂O₃, SiO₂, Al₂O₃, CdO, CaO, BaO, ZnO, SiO₂, Na₂O, PbO, and ZrO which may be used independently or in combination to form glass binders. Typical metal oxides useful in thick film compositions are conventional in the art and can be, for example, ZnO, MgO, CoO, NiO, FeO, MnO and mixtures thereof.

The functional phase and any other powders are typically mixed with an organic medium by mechanical mixing to form a pastelike composition having suitable consistency and rheology for printing. A wide variety of inert liquids can be used as organic medium. The organic medium must be one in which the solids are dispersible with an adequate degree of stability. The rheological properties of the medium must be such that they lend good application properties to the composition. Such properties include: dispersion of solids with an adequate degree of stability, good application of composition, appropriate viscosity, thixotropic, appropriate wettability of the substrate and the solids, a good drying rate, good firing properties, and dried film strength sufficient to withstand rough handling. The organic medium is conventional in the art and is typically a solution of the polymer in solvent(s). The most frequently used resin for this purpose is ethyl cellulose. Other examples of resins include ethylhydroxyethyl cellulose, wood rosin, mixtures of ethyl cellulose and phenolic resins, polymethacrylates of lower alcohols, and monobutyl ether of ethylene glycol monoacetate can also be used. The most widely used solvents found in thick film compositions are ethyl acetate and terpenes such as α- or β-terpineol or mixtures thereof with other solvents such as kerosene, dibutylphthalate, butyl carbitol, butyl carbitol acetate, hexylene glycol and high boiling alcohols and alcohol esters. Various combinations of these and other solvents are formulated to obtain the viscosity and volatility requirements desired.

In addition, the thick film composition can also include other metal particles and inorganic binder particles to enhance various properties of the composition, such as adhesion, sintering, processing, brazeability, solderability, reliability, etc. during processing. Oxalic acid catalyzed alkyl t-butyl/amyl phenolic resin is an example of an adhesion promoter used to increase adhesion of the thick film composition to a support of a transfer sheet which is further described herein below.

In a fireable thick film composition, when firing in the 300 to 1000° C. temperature range, adhesion of the thick film composition to the substrate is generally achieved by the melted glass frit(s) wetting the substrate. The inorganic binder (glass frits, metal oxides and other ceramics) portion of the thick film composition is the focus of adhesion to the substrate. For example, in a traditional thick film conductor composition firing, the sintered metal powders are wetted or interlocked by the inorganic binder, at the same time, the inorganic binder wets or interlocks with the substrate, thus, producing adhesion between the sintered metal powders and the substrate. Hence, for thick film functionality, it is important that the patterning technology deposits a well dispersed thick film composition with all the necessary ingredients within prescribed quantities. For firing temperatures above 1000° C., in addition to inorganic binder wetting/interlocking adhesion mechanisms, other interactions and compound formation could contribute to adhesion mechanisms.

Polymeric thick film compositions are mainly made up of conductive, resistive or dielectric powders, such as those discussed hereinabove, dispersed in an organic medium containing polymer or natural and synthetic resin and solvent, typically volatile solvent and a polymer. They typically do not include glass frit since they are cured and not fired. Some examples of typical polymers employed in polymeric thick film compositions are polyesters, acrylics, vinyl chlorides, vinyl acetates, urethanes, polyurethanes, epoxies, phenolic resin systems, or mixtures thereof. The organic medium is preferably formulated to give appropriate wettability of the particles and the substrate, good drying rate, dried film strength sufficient to withstand rough handling. Satisfactory appearance of the dried composition is also important.

Solvents suitable must dissolve the polymer. Some examples of solvents are listed: propylene glycol monomethyl ether acetate, methyl propanol acetate, 1-methoxy-2 propanol acetate, methyl cellosolve acetate, butyl propionate, primary amyl acetate, hexyl acetate, cellosolve acetate, pentyl propionate, diethylene oxalate, dimethyl succinate, dimethyl glutarate, dimethyl adipate, methyl isoamyl ketone, methyl n-amyl ketone, cyclohexanone, diacetone alcohol, diisobutyl ketone, n-methyl pyrolidone, butyrolactone, isophorone, methyl n-isopropyl ketone. Various combinations of these and other solvents are formulated to obtain the desired viscosity and volatility requirements for the process that the polymer thick film composition is to be employed.

The organic medium is required to impart the necessary adhesion to the desired substrate, and it, also, provides the composition with the required surface hardness, resistance to environment changes and flexibility. Additives as known to those skilled in the art may be employed in the organic medium to fine-tune the viscosity for printing.

After applying a polymer thick film composition on a base material, the composition is typically dried by heating at temperatures of up to about 150° C. which cause the volatile solvents to be driven off or dried. After drying, depending on the application, the composition will undergo a curing process wherein the polymer will bind the powder to form a circuit pattern or other desired result. In order to obtain the desired end properties, one skilled in the art knows it is important that the thick film composition contains an optimized amount of each of the desired ingredients to meet the end result. For example, a thick film silver composition for varistor termination applications, may contain 70+ or −2 percent of a specific silver powder, 2+ or −0.04 percent of a mixture of frits that are compatible with the type of varistor ceramic substrate used, 0.5+ or −0.01 percent of metal oxide adhesion promoter, sintering promoter/inhibitor and the balance being organic medium consisting of polymer(s), solvent(s), surfactant(s), dispersant(s) and other materials commonly used in the art of thick film compositions. The optimized amount of each ingredient is important to achieve the desired thick film conductor, resistor, dielectric or emitter properties. The properties needed may include coverage, density, uniform thickness and circuit pattern dimensions, electrical properties such as: resistivity, current-voltage-temperature characteristics, microwave, radio-high frequency characteristics, capacitance, inductance, etc.; interconnection characteristic properties, such as: solder or braze wetting, compression and wire bonding, adhesive joining, and junction characteristics; optical properties, such as: fluorescence; and other initial and aged/stress testing properties that may be required.

### PROCESS DESCRIPTION AND MATERIALS

The process of the present invention comprises a photosensitive polymer layer that is applied onto a substrate surface. In a patterning process, a photohardenable tacky layer is formed on the substrate surface, and the photohardenable tacky layer is exposed via a photomask having a desired pattern. A pattern is imaged onto a tacky photosensitive polymer layer using actinic radiation; the exposed areas of the polymer layer undergo a chemical change that renders the areas non-tacky. The surface of the photohardenable tacky layer is heated next at a suitable temperature. A subsequent application of a thick film transfer sheet, preferably by lamination, will cause a thick film composition which has electrically functional properties to adhere only at the tacky patterned areas. Upon peeling off the transfer sheet, a thick film print of the pattern will be produced on top of the tacky areas of the imaged photosensitive layer. Typical processing conditions as prescribed by the thick film composition used on the transfer sheet will then be followed.

The new thick film patterning approach comprises the following materials and process steps:

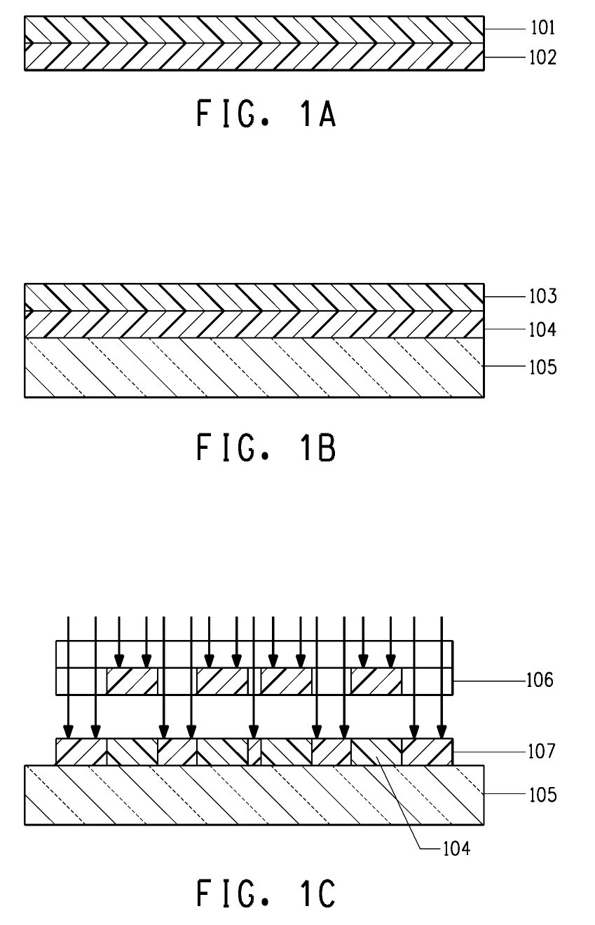

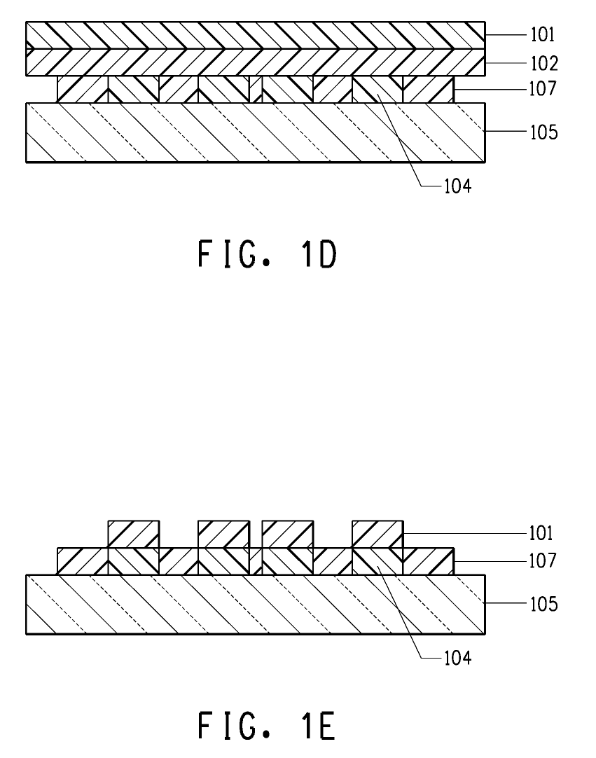

A sheet, referred to as a transfer sheet for illustration purposes, is depicted by FIG. 1(a). It comprises at least one layer of a dried-strippable thick film composition (101), preferably a fireable thick film composition, with powders, inorganic binders and organic mediums as found in the thick film compositions as described hereinabove, deposited on a support (102).

The thick film composition is deposited, for example, by casting, printing or spraying on a strippable support and then dried. During drying the volatile organic solvents are evaporated. The support is a delivery vehicle for applying the dried thick film composition to an imaged photosensitive layer. The dried-strippable thick film composition layer should have sufficient adhesion to the support to remain affixed to the support throughout the required process steps, but at the same time, the adhesive strength of the dried-strippable layer should be carefully balanced with the adhesive strength of the strippable support so the thick film composition could be deposited on an imaged photosensitive layer to carryout the steps in the process of the invention.

The strippable support may comprise almost any material that has reasonable flexibility and integrity. A single layer or multiple layers of a thick film composition may be applied to the support. The support is generally smooth and flat and dimensionally stable. A polyester or polyolefin film e.g. polyethylene polypropylene are examples of suitable supports. Examples of suitable materials that can be used as a support include MYLAR. polyester (polyethylene terepthalate) film available from E. I. du Pont de Nemours and Company and TRESPAPHAN® film available from Hoechst, Winston-Salem, N.C. The support typically has a thickness of 10 to 250 microns. The support may be in sheet form, which may be proportional to the size of the pattern that needs to be created or the support may be in a continuous roll. The roll will allow for continuous mass production. Optionally, a flexible cover sheet may be present on the outmost layer of the dried thick film composition layer. The cover sheet protects the underlaying areas and is easily removable.

In another embodiment of a transfer sheet, multiple layers of thick film compositions may be deposited on a support resulting in a dual-layer transfer sheet. A first layer of the multiple layers may include a silver-containing thick film composition layer cast and dried onto a support. A second layer may include a black thick film composition contrast layer cast and dried on top of the silver thick film layer resulting in two layers of thick film composition on one support.

In another embodiment of a transfer sheet, the components of the thick film composition could be separated. For example, a precious metal with organic medium could be cast onto one support, and inorganic powders with organic medium could be cast onto another support. The process of the invention would then be accomplished in two steps.

The process employs a photosensitive layer having a tacky surface. The photosensitive layer could comprise an optional strippable support or base layer, a photosensitive tacky layer and a strippable cover sheet, wherein the strippable support has greater adhesion to the photosensitive tacky layer than the strippable cover sheet. Actinic radiation impinges on the photosensitive layer containing at least one photoactive component to induce a physical or chemical change in that material. In the photosensitive compositions which are useful in the present invention, exposure to actinic radiation causes a change in the tackiness of the layer. This element would be a positive working element as known in the art of photolithography. Examples would be CROMALIN®. photosensitive products sold by E. I. du Pont de Nemours and Company, Wilmington, Del. Descriptions of positive working photosensitive elements are disclosed in U.S. Pat. Nos. 3,649,268; 4,734,356 (positive working photosensitive elements including a support layer, a photosensitive layer having a binder component, an ethylenically unsaturated monomer component and a photopolymerizable initiator, and optionally a cover sheet); U.S. Pat. No. 4,849,322 (a multilayer element comprising a cover sheet, photo-adherent layer and tonable contiguous layer); U.S. Pat. Nos. 4,892,802; 4,948,704; 4,604,340 and 4,698,293. When using such a photosensitive tacky sheet, the latter is preferably adhered to the substrate while being pressed. Preferably, the photosensitive tacky sheet is adhered to the substrate while being heated. For instance, the photosensitive tacky sheet is placed on the substrate, and is run between two rollers, whereby the sheet becomes adhered to the substrate. The photosensitive tacky sheet becomes adhered more solidly to the substrate when the rollers are heated to a temperature of 50° C. to 90° C. Other than through adhesion of a sheet or a tape in which a photohardenable tacky composition such as the one described above is formed first to a layer shape on a support, the photohardenable tacky layer may also be formed through direct coating of the photohardenable tacky composition onto the substrate. When coating the photohardenable tacky composition directly onto the substrate, using a coating apparatus or the like, care is needed to ensure that the photohardenable tacky composition is applied to a uniform thickness.

In the case where the photosensitive compositions become less tacky to non-tacky (hereinafter referred to as “non-tacky”) when image-wise exposed to actinic radiation, the composition is referred to as “photohardenable”. Photohardenable systems are well known and preferred in the present invention and generally include a photoinitiator or photoinitiator system (hereinafter referred to collectively as “photoinitiator system”), and at least one compound which reacts with the species generated by exposure of the photoinitiator to actinic radiation, causing a decrease in tackiness, an ethylenically unsaturated compound, and a binder. In this context, the photoinitiator system, when exposed to actinic radiation, acts as a source of free radicals needed to initiate polymerization and/or cross-linking of the ethylenically unsaturated compound. Although not limited to photohardenable systems, the photosensitive layer of the element of the invention will be further described in terms of such systems.

The photoinitiator system has one or more compounds that directly furnish free radicals when activated by actinic radiation. The system also may contain a sensitizer that is activated by the actinic radiation, causing the compound to furnish the free radicals. Useful photoinitiator systems can also contain a sensitizer that extends spectral response into the near ultraviolet, visible, and near infrared spectral regions. Photo-initiator systems are well known and discussions of such systems can be found in, for example, “Photo-reactive Polymers: The Science and Technology of Resists” by A. Reiser, John Wiley & Sons, New York, 1989, and “Radiation Curing: Science and Technology” edited by S. P. Pappas, Plenum Press, New York, 1992. The photohardenable tacky composition is explained next. The photohardenable tacky composition comprises a photoinitiator, a polymerizable monomer, an organic binder, a solvent and an additive.

### (A) Photoinitiator

The photopolymerization initiator is explained next. Preferred photoinitiator systems are free radical generating addition polymerization initiators activatable by actinic light and thermally inactive at and below 100 C. These include the substituted or unsubstituted polynuclear quinones such as 9,10-anthroquinone; vicinal ketaldonyl alcohols, such as benzoin; α-hydrocarbon-substituted aromatic acyloins, including α-methylbenzoin; Michler's ketone, benzophenone, hexaarylbiimidazoles in association with hydrogen donors. Particularly preferred photoinitiators include hexaarylbiimidazoles with hydrogen donors; Michler's ketone and ethyl Michler's ketone, particularly in association with benzophenone; and acetophenone derivatives. Essentially, the photoinitiator may be any photoinitiator. Examples of preferred photopolymerization initiators used in the photosensitive resin composition of the present invention include, besides those set forth in U.S. Pat. No. 7,052,824, the compounds below. For example,
1-hydroxy-cyclohexyl-phenyl-ketone,
2-hydroxy-2-methyl-1-phenyl-propan-1-one,
1-[4-(2-hydroxyethoxy)-phenyl]-2-hydroxy-2-methyl-1-propane-1-on,
2-benzil-2-dimethylamino-1-(4-morpholinophenyl)-butanon-1, α-hydroxyalkylphenones such as
2-hydroxy-1-{4-[4-(2-hydroxy-2-methyl-propionyl)-benzyl]phenyl}-2-methyl propan-1-one, or
2-methyl-1-(4-methylthiophenyl)-2-morpholinopropan-1-one, or
2,2-dimethoxy-1,2-diphenylethane-1-one, methylbenzoylformate (Darocure® MBF) could be used as well. These initiators may be used singly or in combinations of two or more.

Among the above photopolymerization initiators, α-aminoalkylphenones are preferably preferred, in particular, in terms of photosensitivity. The addition amount thereof ranges preferably from 0.1 to 6.0 wt %, more preferably from 1.0 to 5.0 wt %, and yet more preferably from 2.0 to 4.0 wt %, relative to the total amount of photohardenable tacky composition. Also, 2-ethylhexyl-4-dimethylaminobenzoate may be further added as a polymerization promoter. The addition amount thereof ranges preferably from 0.1 to 1.0 wt % relative to the total amount of photoinitiator.

### (B) Photopolymerizable Monomer

The ethylenically-unsaturated compound is one which is capable of undergoing free-radical initiated polymerization and/or crosslinking. Such compounds are generally known as a photopolymerizable monomer or oligomers, although polymers having reactive pendant groups can also be used. Such compounds are well known in the art and have been disclosed in, for example, “Light-Sensitive Systems: Chemistry and Application of Nonsilver Halide Photographic Processes” by J. Kosar (John Wiley & Sons, Inc., 1965); “Imaging Processes and Materials-Neblette's Eighth Edition” edited by J. Sturge, V. Walworth and A Shepp (Van Nostrand Reinhold, 1989); and “Photoreactive Polymer-The Science and Technology of Resists” by A. Reiser (John Wiley & Sons, 1989).

Typical monomers are: unsaturated esters of alcohols, preferably esters of polyols with acrylic or methacrylic acid, such as t-butyl acrylate, cyclohexyl acrylate, hydroxy C 1-C 10-alkyl acrylate, butanediol diacrylate, hexamethylene glycol diacrylate, bisphenol A diacrylate, trimethylolpropane triacrylate, polyoxyethylated trimethylolpropane triacrylate, ethylene glycol diacrylate, glycerol triacrylate, ethylene glycol dimethacrylate, pentaaerythritol tri-and tetraacrylate and methacrylate; acryloxy-and methacryloxy-alkyl ethers of bisphenol A, such as di-(3-acryloxy-2-hydroxypropyl) ether of bisphenol A and di-(3-acryloxy-2-hydroxypropyl) ether of tetrabromo-bisphenol A; unsaturated amides, such as 1,6-hexamethylene bisacrylamide; vinyl esters, such as divinyl succinate, divinyl phthalate, and divinyl benzene-1,3-disulfonate; styrene and derivatives thereof; and N-vinyl compounds, such as N-vinyl carbazole. Sarbox® SB510E35 which is a carboxylic acid and anhydride containing methacrylate oligomer blended in ethoxylated trimethylolpropane triacrylate monomer or Sarbox® SB520A20 which is a carboxylic acid containing acrylate oligomer blended in tripropylene glycol diacrylate monomer, Sarbox® SB520E35 which is a carboxylic acid containing acrylate oligomer blended in ethoxylated trimethylolpropane triacrylate monomer is also favorably used.

### (C) Organic Binder and Solvent

The organic binder is a film forming material which may contain reactive groups. Suitable binders that can be used alone or in combination are well known in the art. These include polyacrylate and α-alkyl acrylate esters; polyvinyl esters; ethylene vinyl acetate copolymers; polystyrene polymers and copolymers; vinylidene chloride copolymers; polyvinyl chloride and copolymers; synthetic rubbers; high molecular weight polyethylene oxides of polyglycols; epoxides; copolyesters; polyamides; polycarbonates; polyvinyl acetals; polyformaldehydes. Recently there has been more and more interest in binders which are aqueous processable. For aqueous processability, the binders should be developable by aqueous alkaline solution. By “developable” is meant that the binders are soluble, swellable or dispersible in the developer solution. Preferably, the binder is soluble in the developer solution. Particularly preferred binders are acidic, polymeric, organic compounds. Single or multiple binder compounds can be used. One class of binders which is useful in the process of the invention is vinyl addition polymers containing free carboxylic acid groups. These are prepared from 30-94 mole percent of one or more alkyl acrylates and 70-6 mole percent of one or more α-β ethylenically unsaturated carboxylic acids; more preferably from 61-94 mole percent of two alkyl acrylates and 39-6 mole percent of an α-β ethylenically unsaturated carboxylic acid. Suitable alkyl acrylates for use in preparing these polymeric binders include methyl acrylate, ethyl acrylate, propyl acrylate, butyl acrylate, and the methacrylate analogs. Suitable α-β ethylenically unsaturated carboxylic acids include acrylic acid, methacrylic acid, crotonic acid, maleic acid or maleic anhydride, and the like. Binders of this type, including their preparation, are described in German Application OS 2,320,849, published Nov. 8, 1973. Styrene can be substituted for one of the alkyl acrylate or methacrylate components. Also suitable are copolymers of styrene and substituted styrenes with an unsaturated carboxyl-containing monomer, as described in detail in British Patent 1,361,298. When the organic binder has high viscosity, organic solvent is added in order to adjust the viscosity. The organic solvent could be selected from toluene, xylene, solvent naphtha, normal hexane, cyclohexane, a methylcyclohexane, normal heptane methanol, ethanol, butanol, isopropyl alcohol, normal propyl alcohol, TBA (tertiary butanol), butanediol, ethyl hexanol, benzyl alcohol ethylene glycol monomethyl ether acetate, PMA (propylene glycol monomethyl ether acetate), diethylene glycol monobutyl ether acetate, diethylene glycol monoethyl ether acetate and the like. In the present invention there may also be used a commercially available product comprising a mixture of an organic binder and a solvent. When using such a commercially available product, the viscosity thereof can be adjusted through addition of solvent.

### (D) Additive

Other components as an additive conventionally added to photohardenable compositions can be present to modify the physical properties of the photohardenable tacky layer. Such components include: sensitizer, inhibitor, thickner, plasticizers, thermal stabilizers, optical brighteners, ultraviolet radiation absorbing material, color formers, adhesion modifiers, coating aids, and release agents. In addition, depending on the application, other inert additives can be employed such as dyes, pigments and fillers. These additives are generally present in minor amounts so as not to interfere with the exposure of the compositions.

Typical compositions for the photohardenable layer are, by weight, based on the total weight of the photohardenable layer: photoinitiator system, 0.1 to 10%, preferably 1 to 7%; photopolymerizable monomer, 3 to 60%, preferably 5 to 50%; mixture of binder(s) and solvent, 6 to 90%, preferably 8 to 75%; all other components, 0 to 5%, preferably 0 to 4%. The thickness of the layer varies according to the end use. Generally, the thickness is in the range of 0.7 to 125 microns.

The composition of a sheet-like photohardenable tacky composition has been explained thus far. However, the photohardenable tacky layer may also be formed through coating of a paste-like photohardenable tacky composition having a composition such as the above-described composition. The coating method involves, for instance, placing the paste-like photohardenable tacky composition on a substrate, and spreading the photohardenable tacky composition to a uniform thickness using a coater or the like. A solvent content of 50 to 80 wt % relative to the weight of photohardenable tacky composition affords in that case a viscosity that allows the photohardenable tacky composition to be easily spread. The latter coating method involves, for instance, placing a sheet-like photohardenable tacky composition on a substrate, and causing the photohardenable tacky composition to adhere while being heated and pressed.

It is possible to have more than one photosensitive layer in the photosensitive film. The layers can have the same or different compositions. It is also possible to have non-photosensitive layers, to adjust adhesion or other properties. The overall thickness of all the layers, excluding the support and coversheet, should be in the same range as that listed above for the single photosensitive layer, although greater thicknesses can be used.

FIG. 1(b) illustrates an assembly wherein a removable base layer was removed from a photohardenable layer (104) that has a tacky surface and an optional cover layer (103) such as MYLAR□R□ film, followed by laminating the photohardenable layer onto a substrate (105). Substrates that may be used in the assembly could be rigid or flexible, and permanent or temporary, and are known by those skilled in the art of circuit assembly. Some examples of substrates include: glass panels (for example, a soda lime glass), glass-ceramic, low-temperature co-fired ceramics, alumina, aluminum oxide, and coated substrates, such as porcelainized steel, glazed ceramic substrates, and insulated metal substrates which are insulated with ceramic, glass or polymer. The substrates could be in their fired or green state. The photohardenable layer is sandwiched between the substrate and the cover layer. The cover layer is transparent for actinic radiation penetration and protects the tacky surface of the photohardenable layer.

As illustrated by FIG. 1(c), image-wise exposing the photohardenable layer with actinic radiation through a patterned photomask (106) causes detackification of the exposed areas of the photohardened layer (107) forming a pattern, for example a circuit pattern which would have electrically functional properties. The circuit pattern is a positive image wherein it would be the same as that found on the photomask. In the present invention, the exposure amount is preferably not lower than 100 mJ/cm², more preferably not lower than 150 mJ/cm². The photosensitive resin layer does not cure sufficiently when the exposure amount is lower than 100 mJ/cm². Preferably, the exposure amount does not exceed 1000 mJ/cm², more preferably 850 mJ/cm². Although the photohardenable tacky layer becomes sufficiently cured, the surface thereof fails to do so, on account of the quenching effect, even if the exposure amount exceeds 1000 mJ/cm², which entails excessive energy consumption. In the present invention, exposure can be carried out under conditions of low oxygen concentration. The quenching effect can be suppressed by carrying out exposure in a low-oxygen environment. Means for lowering oxygen concentration include, for instance, nitrogen purging, in which the interior of the exposure apparatus is filled with nitrogen, or vacuum evacuation.

In the method for forming a thick film pattern of the present invention, the photohardenable tacky layer (104) is heated after exposure. The heating temperature is preferably not lower than 50° C. A temperature below 50° C. precludes burning off the tacky composition remaining on the surface of the photohardened layer (107) that has not cured owing to the quenching effect. Such being the case, the heating temperature is preferably not lower than 55° C. Preferably, the heating temperature does not exceed 100° C. A heating temperature exceeding 100° C. causes the photohardenable tacky layer (104) at non-exposed uncured portions to scatter off excessively, as a result of which the thick film composition fails to adhere, and the thick film pattern cannot be formed. Such being the case, a more preferred heating temperature does not exceed 85° C. The heating time is adjusted in accordance with the heating temperature conditions, but, preferably, does not exceed 40 minutes, more preferably 30 minutes. When the heating time is too short, the curing portions of the photohardenable tacky layer fail to be exposed. Therefore, the heating time is preferably no shorter than 3 minutes, more preferably no shorter than 5 minutes.

As regards the relationship between heating temperature and heating time, the heating temperature ranges preferably from 75 to 100° C. when the heating time is less than 15 minutes. When the heating time is 15 minutes to less than 40 minutes, the heating temperature ranges preferably from 45 to 75° C.

FIG. 1(d) illustrates the transfer sheet (thick film material side facing the imaged photohardenable layer) laminated onto the photohardenable tacky layer (104) and the photohardened layer (107). The thick film composition (101) will substantially adhere to the unexposed tacky areas of the photohardenable layer. After peeling the used transfer sheet, which has a reverse circuit pattern formed thereon, off of the photohardenable layer, a thick film circuit pattern is produced forming an article as illustrated in FIG. 1(e). The above process may be repeated, i.e., photohardenable layer, imaging, applying transfer sheet, at least once until desired layer number is reached. The article will then undergo a firing step.

Optionally, depending on the application of the assembly, the assembly may undergo a heat treatment which causes the thick film circuit pattern to diffuse through the tacky non-hardened photohardenable layer onto the substrate surface. This is then followed by a firing step.

The presently available materials that make up the photohardenable layer will be fired or burned-out at about 400° C. Thus, if complete burnout and removal of the photohardenable layer is desired, then the recommended firing temperature should be above 400° C.

In order to achieve adhesion of the thick film composition when firing in the 400 to 1000° C. temperature range, it was mentioned that a glass frit/inorganic binder system in the thick film composition is important. In some special cases, this requirement might not be necessary. When an inorganic binderless thick film composition is applied to a substrate that contains dielectric or glassy components with a softening point close to the firing/sintering temperature of the binderless thick film composition, then the substrate surface itself can replace the role of the glass/inorganic powders in the traditional thick film composition. Additionally, if the conductive, resistive or dielectric powder itself is coated with some kind of glass or ceramic (or mixture thereof), this coating could act as the inorganic binder system of the thick film composition. The glass/ceramic coating can be applied in a number of ways including spraying, solution dipping, aerosol reduction, precipitation, vapor deposition, tumbling and so on. The coated particles could be heat treated for a uniform and robust coating.

In another embodiment, it is possible to skip the exposure or imaging step of the photohardable layer disposed on a substrate as described above. In absence of an imaging step, once the cover sheet of the photohardenable layer is removed the entire surface of the photohardenable layer will remain tacky. Upon lamination of a transfer sheet to the tacky photohardenable layer and removal of the sheet, the thick film composition of the transfer sheet will substantially remain on the photohardenable layer. Therefore, the pattern created will be full coverage of the unexposed area. This is especially useful in dielectric thick film composition applications.

### EXAMPLES

### (A) Formation of Transfer Sheet

Process for casting a thick film silver containing composition on TRESPAPHAN® support is described. The transfer sheet produced is used in Examples herein below unless otherwise specified in the example. All percentages are in weight percent unless otherwise stated. In a stoneware ceramic jar, the following ingredients were added: Alumina Beads, filling the jar about 40 percent. The composition is 58.5 wt % Organic Medium Composition □82wt % of acetic ether□6 wt % of methyl ethyl ketone, 2 wt % of diethylene glycol diethyl ether, 0.5 wt % of dibutyl phthlate, 2 wt % of ethylcellulose, 7.5 wt % of VARCUM®□, 37.5 wt. % silver powder (spherical silver, D50 0.1 to 3 μm), 1.0 wt. % Bi—Al—B based glass frit, 3.0 wt % Ethyl acetate. The mixture is jar milled for 12 to 15 hours, the beads screened and the composition is cast on TRESPAPHAN® sheet made by Hoechst TRESPAPHAN® of Winston-Salem, N.C., using a doctor blade with an opening of 15 micrometers. VARCUM® Resin was available from Schenectady international, Schenectady, N.Y. The cast sheet is air dried for 15 minutes followed by oven drying at 80° C. for 10 minutes. The silver-coated transfer sheet is ready for use.

### (B) Formation of Photohardenable Tacky Composition

The photohardenable tacky composition for forming the positive photohardenable tacky layer was manufactured on the basis of the following composition. 10 wt % of Acrylic Polymer as an organic binder and 75.7 wt % of Propylene glycol methyl ether acetate as a solvent were mixed. Then 2.1 wt % of bisphenol A diacrylate, 1.8 wt % of Sarbox® SB510E35 (Sartomer Corporation) and 3.1 wt % of trimethylolpropane triacrylate as a monomer were added to the mixture of the organic binder and solvent. 1.5 wt % of alkylphenon type photoinitiator and 1.1 wt % of Methylbenzoylformate (Darocure® MBF, Ciba Corporation) were added as photo-initiators. Then 2-ethylhecyl-4-dimethylaminobenzoate, TAOBON, N,N-diethyl hydrocylamine and triacetine were added as additives to photohardenable tacky composition. The materials were mixed well to be a photohardenable tacky composition.

### (C) Formation of an Electrode

A glass substrate 350 mm long, 300 mm wide and 2.8 mm thick was coated with the photohardenable tacky composition prepared in (B) over 280 mm lengthwise and 300 mm across, to a film thickness after drying of 20 μm. An automatic coater (PI-1210 and SA-203, Tester Sangyo Co., Ltd.) was used for coating. The photohardenable tacky layer was exposed via a photomask (Line type with 100 μm width). After exposure, the photohardenable tacky layer having an image formed thereon was heated. The exposure conditions and heating conditions are given in Table 1. A transfer sheet was laminated onto the imaged film (with the thick film side of the transfer sheet facing the imaged layer). Peeling the transfer sheet produced the desired pattern where the unexposed areas of the imaged film layer remained tacky and the thick film was disposed on the tacky areas. The structure was fired at 500° C. in air using a standard thick film firing profile for displays

### Results

Articles having a continuous line pattern formed thereon and having an average line width of 100 μm±5 μm were rated as A; articles having a line pattern formed thereon but with a thick film composition residue between lines, and articles having no residue but exhibiting sites at which lines were intermittently broken, halfway along the line, were rated as B; and articles in which the thick film composition was transferred over the whole surface, or in which the thick film composition failed completely to adhere, or in which the lines did not form, were rated as C.

In the Comparisons, which were not heated after exposure, the thick film composition was transferred over substantially the entire surface, and no line pattern formed. This is believed to arise from the fact that the surface of the photohardenable tacky layer remained uncured, on account of the quenching effect, also in exposure regions. Although a line pattern formed in Example 2, some residue was observable in parts between lines. Presumably, this was brought about through insufficient heating temperature, heating time or exposure amount, which precluded the uncured layer, resulting from the quenching effect, from burning off sufficiently, as a result of which the thick film composition adhered partially to portions other than those of the desired pattern. In Example 4 and Example 5, lines formed, but with observable breaks. This is believed to arise from excessive heating temperature, heating time or exposure amount, which caused the tacky composition, at portions that are to remain uncured by not being exposed, to partly burn off, which precluded the thick film composition from being transferred as a continuous line pattern. A good continuous line pattern was formed in Example 1 and Example 3. It is found, therefore, that the optimal range of conditions that allows a good thick film pattern to be formed includes a heating temperature of 60° C., a heating time of 20 minutes and an exposure amount of 800 mJ/cm², as well as a heating temperature of 80° C., a heating time of 10 minutes and an exposure amount of 800 mJ/cm², even when exposing the photohardenable tacky layer without a cover sheet.

Although the above results show that a good thick film pattern can be formed even when exposing the photohardenable tacky layer without a cover sheet, a good line pattern can conceivably be formed by adjusting the conditions of heating temperature, heating time and exposure amount to be other than the conditions that apply in Examples 1 to 5. Specifically, it is thought that an excellent line pattern can be formed, for instance, with a heating temperature of 90° C., a heating time of 10 minutes and an exposure amount of 200 mJ/cm², or with a heating temperature of 50° C., a heating time of 30 minutes and an exposure amount of 800 mJ/cm².

TABLE 1

| | Heating | | Exposure | |
|---|---|---|---|---|
| | temperature | Heating time | amount | |
| Conditions | (° C.) | (min) | (mJ/cm²) | Evaluation |
| Example 1 | 60 | 20 | 800 | A |
| Example 2 | 80 | 10 | 400 | B |
| Example 3 | 80 | 10 | 800 | A |
| Example 4 | 80 | 20 | 200 | B |
| Example 5 | 80 | 20 | 800 | B |
| Comparison 1 | — | — | 200 | C |
| Comparison 2 | — | — | 400 | C |
| Comparison 3 | — | — | 800 | C |

What is claimed is:

1. A process for forming a pattern having electrically functional properties on a substrate comprising the steps of:
(a) providing a photosensitive layer having a tacky surface disposed on a substrate;
(b) image-wise exposing the photosensitive tacky surface to form an imaged layer having tacky and non-tacky areas;
(c) heating the photosensitive layer
(d) applying a sheet comprising at least one layer of a thick film composition disposed on a support to the imaged layer wherein the imaged layer is in contact with the thick film composition of the sheet;
(e) removing the support wherein the thick film composition remains on the support in the non-tacky areas of the imaged layer and the thick film composition substantially adheres to the tacky areas of the imaged layer forming a patterned article; and
(f) firing or curing the thick film composition of the patterned article.

2. A process for forming a pattern having electrically functional properties on a substrate of claim 1 wherein the heating temperature in the step (c) is from 50° C. to 100° C.

3. A process for forming a pattern having electrically functional properties on a substrate of claim 1 wherein the heating time in the step (c) is from 3 minutes to 40 minutes.

4. A process for forming a pattern having electrically functional properties on a substrate of claim 1 wherein the exposure amount in the step (b) is from 100 mJ/cm² to 1000 mJ/cm².
